(19) United States
(12) Patent Application Publication
(10) Pub. No.: US 2014/0161978 A1
(43) Pub. Date: Jun. 12, 2014

(54) METHOD AND APPARATUS FOR FORMING C/SiC FUNCTIONALLY GRADED COATING

(71) Applicant: Industry-Academic Cooperation Foundation, Yonsei University, Seoul (KR)

(72) Inventors: Doo Jin CHOI, Seoul (KR); YooYoul CHOI, Seoul (KR)

(73) Assignee: Industry-Academic Cooperation Foundation, Yonsei University, Seoul (KR)

(21) Appl. No.: 14/077,502

(22) Filed: Nov. 12, 2013

(30) Foreign Application Priority Data
Dec. 6, 2012 (KR) 10-2012-140736

(51) Int. Cl. C23C 16/32

(52) U.S. Cl. CPC C23C 16/325
USPC 427/249.15; 118/715

(57) ABSTRACT

According to an embodiment of the invention, provided is a method of forming a C/SiC functionally graded coating. In the embodiment, in a step of forming the C/SiC functionally graded coating, a reaction condition is controlled by feeding a larger amount of the oxygen gas at an early stage than a latter stage of the reaction so that a pure carbon film is formed on a surface of the substrate and then gradually decreasing the amount of the oxygen gas so that a SiC film having a higher concentration with an increasing distance from the surface of the substrate is formed.

### CROSS REFERENCE TO RELATED APPLICATION

The present application claims priority from Korean Patent Application Number 10-2012-0140736 filed on Dec. 6, 2012, the entire contents of which are incorporated herein for all purposes by this reference.

### BACKGROUND OF THE INVENTION

1. Field of the Invention

The present invention relates to a technology for forming a coating on the surface of a substrate, and more particularly, to a method and apparatus for forming a C/SiC functionally graded coating on the surface of a substrate.

2. Description of Related Art

When forming a coating on the surface of a substrate, it is required to form the coating at a certain thickness or greater in order to achieve the intended effects. However, when the coating is formed as a single film, the coating is peeled from the substrate or microcracks occur at high temperatures due to a difference in the coefficient of thermal expansion (CTE) or the like, which is problematic.

For instance, SiC is a ceramic material that has superior resistance to chemicals, oxidation, heat and wear. In the related art, it was attempted to improve the chemical resistance, oxidation resistance, heat resistance and wear resistance of metal by coating it with SiC through thermal spray coating or chemical deposition. However, these methods present some problems. For example, it is impossible to form the SiC coating on low melting point metal, or cracks occur in the coating or the coating is peeled off due to a difference in the coefficient of thermal expansion (CTE). (See, for example, Korean Patent No. 10-824275.)

In order to prevent these problems, there is proposed a C/SiC functionally graded coating which is formed stepwise. According to a related-art method of fabricating the C/SiC functionally graded coating, the C/SiC functionally graded coating is formed by separately using a silicon-based gas and a carbon-based gas. However, the silicon-based gas is expensive, is very harmful to the human body, and requires a specialized treatment environment.

The information disclosed in the Background of the Invention section is provided only for better understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method and apparatus for forming a C/SiC functionally graded coating on the surface of a substrate without using a silicon-based gas that is harmful to the human body and expensive.

In an aspect of the present invention, provided is a method of forming a C/SiC functionally graded coating. The method includes the following steps of: placing a substrate on which the C/SiC functionally graded coating is to be formed inside a reaction furnace in which the C/SiC functionally graded coating is formed; heating the reaction furnace; and forming the C/SiC functionally graded coating on the substrate by feeding a reactant gas containing carbon and silicon together with oxygen gas into the reaction furnace to cause a reaction between the reactant gas and the oxygen gas. The step of forming the C/SiC functionally graded coating controls a reaction condition by feeding a larger amount of the oxygen gas at an early stage than a latter stage of the reaction so that a pure carbon film is formed on a surface of the substrate and then gradually decreasing the amount of the oxygen gas so that a SiC film having a higher concentration with an increasing distance from the surface of the substrate is formed.

According to an exemplary embodiment of the present invention, a flow rate of the oxygen gas may be controlled such that a ratio of the carbon and the silicon in the reactant gas to the oxygen gas is about 2 at the early stage of the reaction.

The SiC film may be formed on an uppermost layer of the C/SiC functionally graded coating by stopping feeding the oxygen gas at the latter stage of the reaction.

A pressure inside the reaction chamber may be maintained below about 50 torrs.

A temperature inside the reaction chamber may be decreased as the ratio of the carbon and the silicon in the reactant gas to the oxygen gas increases at the step of forming the C/SiC functionally graded coating.

The reactant gas may be implemented as methyltrichlorosilane (MTS), in which the reaction furnace may be heated to a temperature ranging approximately from 1,100 to 1,300° C.

In another aspect of the present invention, provided is an apparatus for forming a C/SiC functionally graded coating on a substrate. The apparatus includes a deposition chamber which performs a deposition process of depositing a predetermined material on the substrate placed on a mounting part and a gas feed system which feeds a reactant gas into the deposition chamber. The gas feed system may include: a reactant source connected to the deposition chamber, the reactant source supplying a reactant required for deposition inside the deposition chamber, the reactant containing carbon and silicon; a carrier gas source connected to the deposition chamber and the reactant source, the carrier gas source supplying a carrier gas which carries the reactant gas into the deposition chamber; an oxygen gas source connected to the deposition chamber, the oxygen gas source supplying oxygen that reacts with the reactant gas that is fed into the deposition chamber; and a control unit which controls flow rates of the reactant gas and the oxygen gas. The deposition chamber may include a reaction furnace capable of staying in vacuum and at high temperature. One end of the reaction furnace is connected to the gas sources and the reactant source which supply the gases, and a vacuum pump is connected to the other end of the reaction furnace. The deposition chamber may further include a heating element which is disposed around the reaction furnace to heat the reaction furnace. The substrate on which the coating is to be formed may be disposed inside the reaction furnace. The control unit may control the flow rates of the oxygen gas in the process of forming the C/SiC functionally graded coating by feeding a larger amount of the oxygen gas at an early stage than a latter stage of the reaction so that a pure carbon film is formed on a surface of the substrate and then gradually decreasing the amount of the oxygen gas so that a SiC film having a higher concentration with an increasing distance from the surface of the substrate is formed.

According to an exemplary embodiment, the control unit may control the flow rate of the oxygen gas such that a ratio of the carbon and the silicon in the reactant gas to the oxygen gas is about 2 at the early stage of the reaction.

The control unit may stop feeding the oxygen gas at the latter stage of the reaction such that the SiC film is formed on an uppermost layer of the C/SiC functionally graded coating.

A pressure inside the reaction chamber may be maintained below about 50 torrs.

The reaction chamber may be configured such that a temperature inside the reaction chamber decreases as the ratio of the carbon and the silicon in the reactant gas to the oxygen gas increases at the step of forming the C/SiC functionally graded coating.

According to the present invention as set forth above, unlike the related art, it is possible to form a C/SiC functionally graded coating on the surface of a substrate without using a silicon-based gas that is harmful to the human body and is expensive.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a block diagram schematically showing the configuration of an apparatus for forming a C/SiC functionally graded coating according to an embodiment of the present invention;

FIG. 2 is a view showing the structure of a deposition chamber (furnace) according to an embodiment of the present invention;

FIG. 3 is a view schematically showing the structures of C/SiC functionally graded coatings formed on two types of substrates (a carbon substrate and an alumina substrate) according to an embodiment of the invention;

FIG. 4 is a view showing the result of an X-ray photoelectron spectroscopy (XPS) analysis on the composition of a coating formed on the surface of a substrate when the flow rate of MTS is fixed to 10 sccm and the flow rates of oxygen are set to 0, 2.5, 5 and 10 sccm;

FIG. 5 is a view showing the result of an X-ray diffraction (XRD) analysis on a coating formed on a substrate when the flow rate of MTS is fixed to 10 sccm and the flow rates of oxygen are set to 0 and 5 sccm; and

FIG. 6 is a view showing a deposition process of forming a C/SiC functionally graded coating according to an embodiment of the present invention.

### DETAILED DESCRIPTION OF THE INVENTION

Reference will now be made in detail to various embodiments of the present invention, examples of which are illustrated in the accompanying drawings and described below. In the following description of the present invention, detailed descriptions of the components that are well-known in the art as for the formation of a C/SiC functionally graded coating will be omitted. In particular, detailed descriptions of the components for feeding a source gas, a carrier gas or the like into a chamber will be omitted, since those components are well-known in the art. Although such descriptions are omitted, the features of the present invention will be apparent to a person having ordinary skill in the art upon reading the following description.

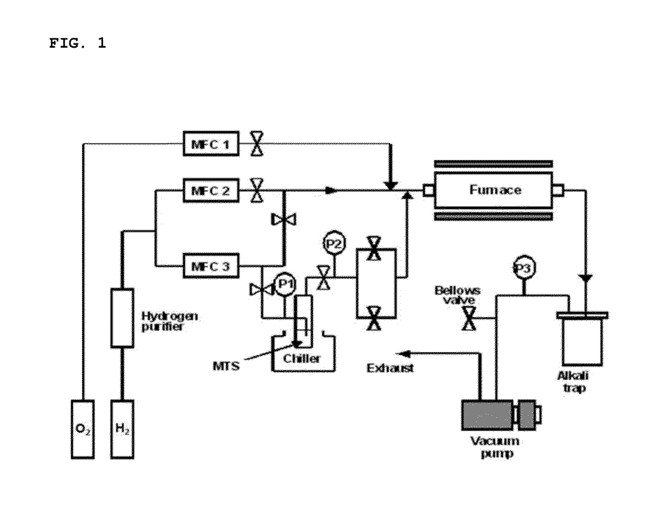

FIG. 1 is a block diagram schematically showing the configuration of an apparatus for forming a C/SiC functionally graded coating according to an embodiment of the present invention.

The apparatus according to this embodiment generally includes a furnace and a gas feed system. The furnace performs the process of forming a certain material, i.e. a C/SiC functionally graded coating, on a substrate mounted on a susceptor (not shown), and the gas feed system feeds a reactant gas into the furnace.

The furnace is a hot wall-type horizontal deposition chamber that can be used at high temperature, and can be made of alumina.

The gas feed system includes a reactant source. The reactant source is connected to the furnace. According to an embodiment of the present invention, an organic substance source including silicon and carbon, for example, methyltrichlorosilane (MTS), or CH₃SiCl₃, in which the content ratio of Si to C is 1:1, is used as a reactant. According to an embodiment of the present invention, the organic substance source is evaporated before being fed into the furnace, while the gas of the organic substance source is fed into the furnace. A vacuum gauge P1 is disposed between the organic substance source and the furnace. The vacuum gauge P1 indicates the pressure of the organic substance source that is being fed. A user can adjust the pressure of the organic substance source to be fed to an intended value (e.g. 10 torrs) by reading the pressure indicated on the vacuum gauge P1.

In addition, the gas feed system includes a carrier gas source. The carrier gas source is connected to the furnace, and feeds a carrier gas for carrying the MTS into the furnace. According to an embodiment of the present invention, the carrier gas is implemented as hydrogen (H₂) gas or argon (Ar) gas, and the flow rate of the carrier gas is controlled using a mass flow controller MFC3. The carrier gas supplied from the carrier gas source is fed into the organic substance source under the control of the mass flow controller MFC3. The organic substance source evaporates a liquid reactant into a gaseous reactant with which the hydrogen gas is mixed through bubbling. The mixture, i.e. the carrier gas and the organic substance source gas, is fed into the furnace. Here, the bubbler, or chiller, is maintained at a constant temperature of 0° C.

Since the mixture of the organic substance source gas and the carrier gas is required to maintain a suitable concentration, the gas feed system includes a dilution gas source. The dilute gas source is also connected to the furnace, and the flow rate of a dilute gas is controlled using a mass flow controller MFC2. According to an embodiment of the present invention, the dilute gas is implemented as hydrogen or nitrogen.

In addition, the gas feed system also includes an oxygen gas source connected to the furnace, and the flow rate of an oxygen gas is controlled by a mass flow controller MFC1. The oxygen supplied from the oxygen gas source serves to produce a C/SiC functionally graded coating on the substrate depending on its flow rate inside the furnace, which will be described later.

In addition, the apparatus according to the present invention can further include an exhaust system. A byproduct, for example, HCl, is produced by the reaction inside the furnace, and an alkali trap is provided in order to neutralize the byproduct. NaOH provided inside the alkali trap reacts with HCl, which is by-produced inside the furnace, thereby neutralizing HCl. A vacuum pump is also provided in order to absorb and discharge several gases that are produced during this neutralization. A bellows valve is provided in order to adjust the pressure of the vacuum pump. A vacuum gauge P3 provided between the bellows valve and the alkali trap displays the pressure inside the furnace. A user can read the pressure displayed on the vacuum gauge P3, and adjust the pressure inside the furnace to an intended deposition pressure (e.g. 50 torrs) during a deposition reaction inside the furnace.

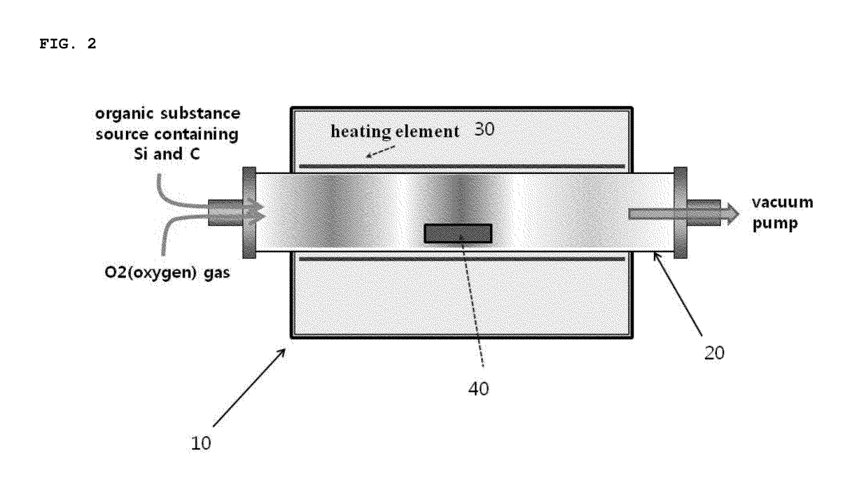

FIG. 2 shows the structure of a furnace 10 for forming a C/SiC functionally graded coating according to an embodiment of the present invention.

As shown in FIG. 2, a C/SiC functionally graded coating-forming tube 20 is disposed inside the furnace 10 such that it stays in vacuum and at high temperature. Gases such as a silicon-based source gas (MTS), oxygen gas, a dilute gas and carrier gases supplied from the gas feed system are fed through one end of the C/SiC functionally graded coating-forming tube 20. The other end of the C/SiC functionally graded coating-forming tube 20 is connected to the vacuum pump, whereby the inside of the C/SiC functionally graded coating-forming tube 20 is maintained in vacuum and gases produced inside the C/SiC functionally graded coating-forming tube 20 are discharged to the outside.

A heating element 30 is disposed around the C/SiC functionally graded coating-forming tube 20, and serves to heat the C/SiC functionally graded coating-forming tube 20 (e.g., about 1,000° C. or above). The temperature inside the tube is measured using a thermocouple device (not shown), and feeding of source substances is started when the tube has arrived at an intended temperature. It was discovered that methyltrichlorosilane (MTS) decomposed at a temperature ranging from 1,100 to 1,300° C. when MTS was used for the organic substance source. Therefore, according to an embodiment of the present invention, the tube is heated to a temperature of 1,000° C. or above, preferably, a temperature ranging from 1,100 to 1,300° C.

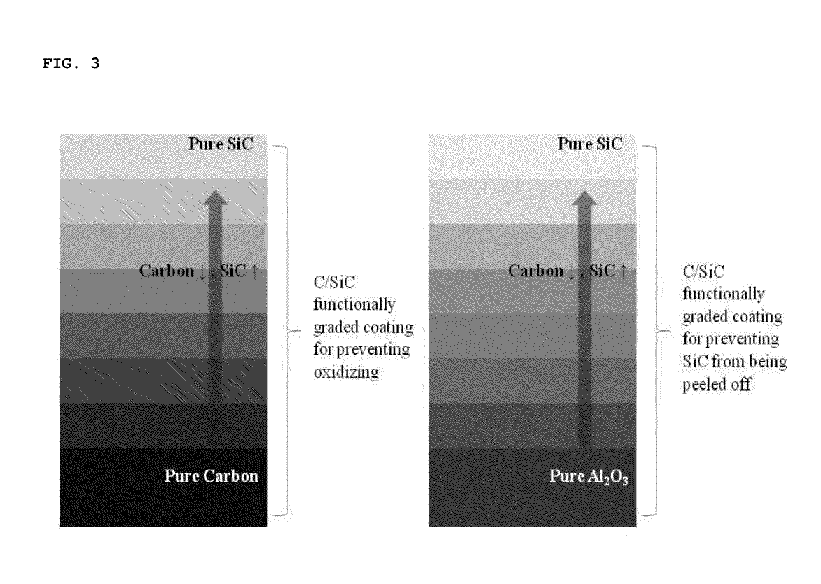

A porous substrate 40 is placed on a susceptor (not shown) inside the tube 20. According to an embodiment of the present invention, the substrate can be implemented as a carbon substrate or alumina (Al₂O₃) substrate. As shown in FIG. 3, when the carbon substrate is used for the substrate 30, it is possible to prevent carbon from oxidizing by forming a C/SiC functionally graded coating, the SiC concentration thereof increasing as it becomes farther away the surface of the substrate, on a carbon film having a high carbon concentration. When the alumina substrate is used for the substrate 30, it is possible to form a C/SiC functionally graded coating, the SiC concentration thereof increasing as it becomes farther away from the surface of the substrate, on a carbon film having a high carbon concentration, thereby preventing the SiC film from being peeled from the surface of the substrate.

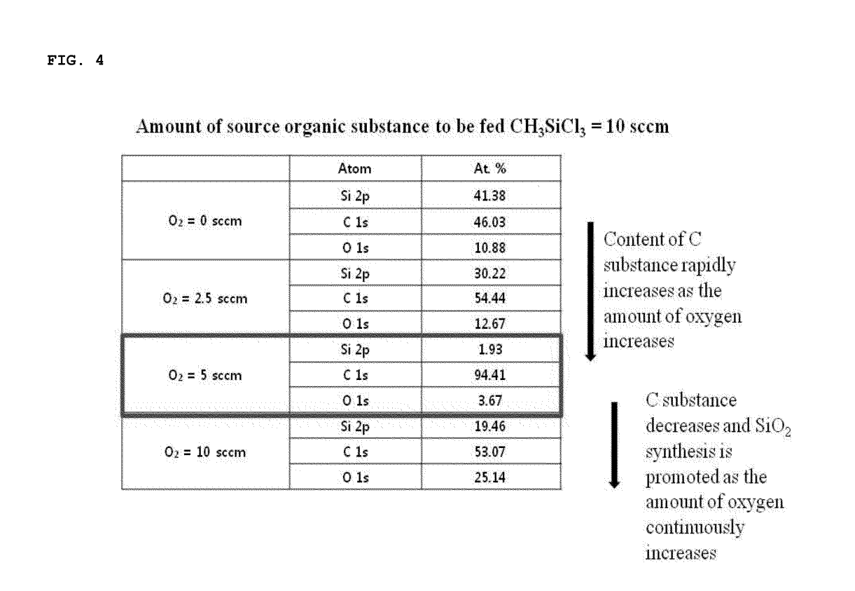

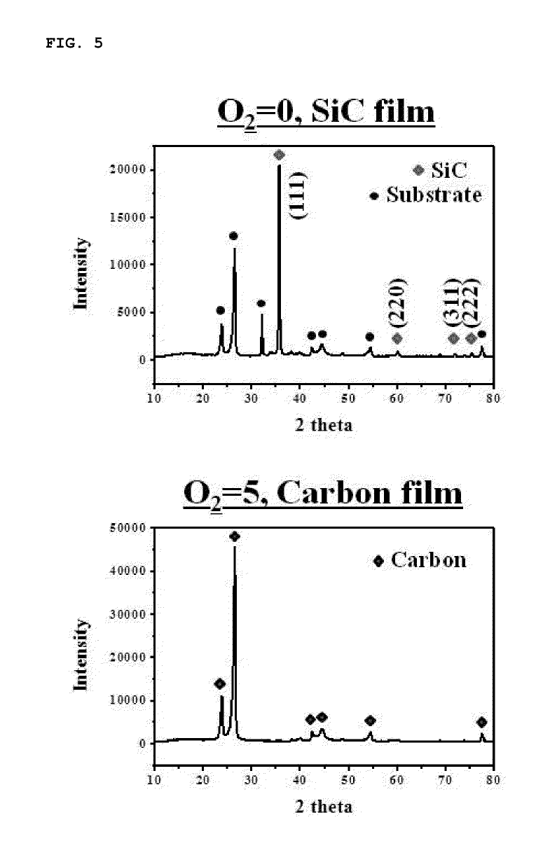

As shown in FIG. 2, according to the present invention, not only the organic substance source, for example, MTS, but also oxygen is fed into the tube 20. The inventors analyzed the composition of the coating formed on the substrate by changing the flow rate of oxygen while fixing the flow rate of MTS to 10 sccm, and the results are presented in FIG. 4 and FIG. 5. FIG. 4 shows the result of an X-ray photoelectron spectroscopy (XPS) analysis on the composition of a coating formed on the surface of a substrate when the flow rate of MTS is fixed to 10 sccm and the flow rates of oxygen are set to 0, 2.5, 5 and 10 sccm. FIG. 5 shows the result of an X-ray diffraction (XRD) analysis on a coating formed on a substrate when the flow rate of MTS is fixed to 10 sccm and the flow rates of oxygen are set to 0 and 5 sccm.

First, as shown in FIG. 4, it is apparent that the content of carbon rapidly increases as the amount of oxygen increases. It is also apparent that carbon decreases and SiO₂ synthesis is promoted when the amount of oxygen increases at a flow rate exceeding 5 sccm. That is, the optimum flow rate of oxygen for the formation of the carbon film is 5 sccm.

In addition, as presented in the XRD analysis result in FIG. 5, it can be appreciated that the carbon film is substantially formed on the surface of the substrate when the flow rate of oxygen is 5 sccm, and the SiC film is formed on the substrate when the flow rate of oxygen is 0 sccm. Based on this result, it can be understood that the C/SiC functionally graded coating, in which the carbon film is formed on the surface of the substrate inside the tube and the carbon content decreases and the SiC content increases as it becomes farther away from the surface, can be produced by feeding an excessive amount of oxygen at the early stage of the reaction between the organic substance source gas and the oxygen gas so that the carbon film is formed on the substrate surface, gradually decreasing the flow rate of oxygen, and then stopping the feed of oxygen at the latter stage.

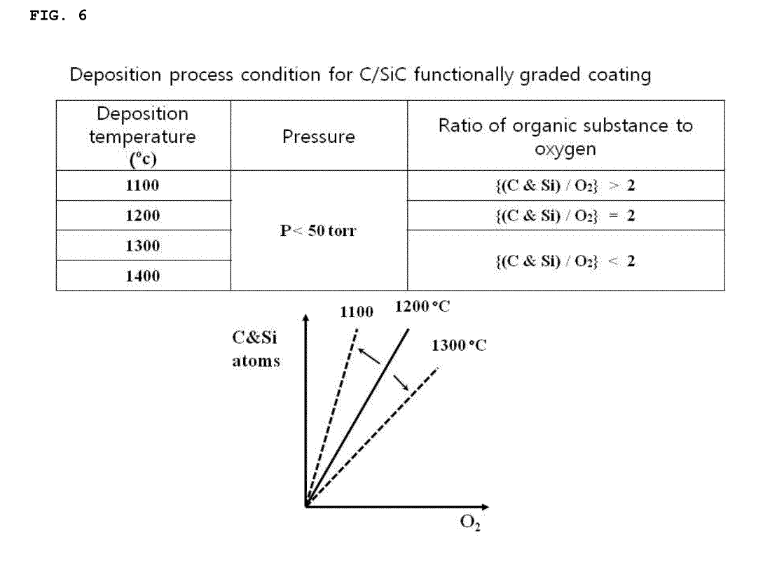

In addition, the inventors discovered process conditions for forming the C/SiC functionally graded coating based on the above-mentioned experiment result, and the discovered results are presented in FIG. 6.

As shown in FIG. 6, the pressure inside the tube 20 is required to stay below 50 torrs. According to the experiments of the inventors, a carbon film was not formed and a SiC film was not properly formed under a pressure above 50 torrs. Therefore, the pressure is set to be below 50 torrs.

In addition, it was discovered that the temperature of the functionally graded coating changes depending on the ratio of carbon and silicon to oxygen in the organic substance source. The carbon film was properly formed when MTSF was set to 10 sccm and the flow rate of oxygen was set to 5 sccm. This indicates that the ratio of C and Si to O₂ is about 2. Based on this, the temperature where the functionally graded coating is formed is changed while the ratio is being changed, and the results are presented in FIG. 6. As shown in FIG. 6, it was discovered that the C/SiC functionally graded coating can be produced at a lower deposition temperature as the ratio of C and Si in the organic substance source increases, and the carbon film can be easily formed when a larger amount of oxygen is fed as the deposition temperature increases. It is possible to produce an intended coating by properly adjusting the deposition temperature and the flow rates of the organic substance source and oxygen depending on the environment where the coating is to be formed. This constitutes one of the characteristic features of the present invention that was not proposed in the related art.

Although the present invention has been described hereinabove with respect to the exemplary embodiments, it should be understood that the present invention is not limited to the foregoing embodiments. For example, a control unit which controls the flow rate of oxygen can be additionally provided. This control unit allows a large flow rate of oxygen to be fed at an early stage such that a carbon film is formed and gradually decreases the flow rate of oxygen such that a C/SiC functionally graded coating is formed. It should be understood that the present invention can be variously altered and modified within the scope of the appended claims and all such alterations and modifications fall within the scope of the present invention. Therefore, the present invention shall be defined by only the claims and their equivalents.

1. A method of forming a C/SiC functionally graded coating, the method comprising the following steps of:
placing a substrate on which a C/SiC functionally graded coating is to be formed inside a reaction furnace in which the C/SiC functionally graded coating is formed;
heating the reaction furnace, and
forming the C/SiC functionally graded coating on the substrate by feeding a reactant gas containing carbon and silicon together with oxygen gas into the reaction furnace to thus cause a reaction between the reactant gas and the oxygen gas,
wherein in the step of forming the C/SiC functionally graded coating, a reaction condition is controlled by feeding a larger amount of the oxygen gas at an early stage than a latter stage of the reaction so that a substantially pure carbon film is formed on a surface of the substrate and then gradually decreasing the amount of the oxygen gas so that a SiC film having a higher concentration with an increasing distance from the surface of the substrate is formed.

2. The method according to claim 1, wherein a flow rate of the oxygen gas is controlled such that a ratio of the carbon and the silicon in the reactant gas to the oxygen gas is about 2 at the early stage of the reaction.

3. The method according to claim 1, wherein the SiC film is formed on an uppermost layer of the C/SiC functionally graded coating by stopping feeding the oxygen gas at the latter stage of the reaction.

4. The method according to claim 3, wherein a pressure inside the reaction chamber is maintained below about 50 torrs.

5. The method according to claim 3, wherein in the step of forming the C/SiC functionally graded coating, a temperature inside the reaction chamber is decreased as the ratio of the carbon and the silicon in the reactant gas to the oxygen gas increases.

6. The method according to claim 4, wherein the reactant gas is implemented as methyltrichlorosilane (MTS).

7. The method according to claim 6, wherein the reaction furnace is heated to a temperature ranging approximately from 1,100 to 1,300° C.

8. An apparatus for forming a C/SiC functionally graded coating on a substrate, the apparatus comprising:
a deposition chamber which performs a deposition process of depositing a predetermined material on the substrate placed on a mounting part, and
a gas feed system which feeds a reactant gas into the deposition chamber,
wherein the gas feed system comprises:
a reactant source which is connected to the deposition chamber and supplies a reactant required for deposition inside the deposition chamber, the reactant containing carbon and silicon;
a carrier gas source which is connected to the deposition chamber and the reactant source and supplies a carrier gas carrying the reactant gas into the deposition chamber;
an oxygen gas source which is connected to the deposition chamber and supplies oxygen reacting with the reactant gas that is fed into the deposition chamber, and
a control unit which controls flow rates of the reactant gas and the oxygen gas,
wherein the deposition chamber comprises:
a reaction furnace that can stay in vacuum and at high temperature and has one end connected to the gas sources and the reactant source which supply the gases, and the other end connected to a vacuum pump, and
a heating element which is disposed around the reaction furnace to heat the reaction furnace,
wherein the substrate on which the coating is to be formed is disposed inside the reaction furnace, and
wherein in a process of forming the C/SiC functionally graded coating, the control unit is configured to control the flow rates of the oxygen gas by feeding a larger amount of the oxygen gas at an early stage than a latter stage of the reaction so that a substantially pure carbon film is formed on a surface of the substrate and then gradually decreasing the amount of the oxygen gas so that a SiC film having a higher concentration with an increasing distance from the surface of the substrate is formed.

9. The apparatus according to claim 8, wherein the control unit is configured to control the flow rate of the oxygen gas such that a ratio of the carbon and the silicon in the reactant gas to the oxygen gas is about 2 at the early stage of the reaction.

10. The apparatus according to claim 8, wherein the control unit is configured to stop feeding the oxygen gas at the latter stage of the reaction such that the SiC film is formed on an uppermost layer of the C/SiC functionally graded coating.

11. The apparatus according to claim 10, wherein a pressure inside the reaction furnace is maintained below about 50 torrs.

12. The apparatus according to claim 10, wherein the reaction furnace is configured such that a temperature inside the reaction chamber decreases as the ratio of the carbon and the silicon in the reactant gas to the oxygen gas increases in the process of forming the C/SiC functionally graded coating.

13. The apparatus according to claim 11, wherein the reactant gas is implemented as methyltrichlorosilane (MTS).

14. The apparatus according to claim 13, wherein the reaction furnace is heated to a temperature ranging approximately from 1,100 to 1,300° C.
